(19) United States
(12) Patent Application Publication
(10) Pub. No.: US 2025/0359020 A1
(43) Pub. Date: Nov. 20, 2025

(54) SEMICONDUCTOR MEMORY DEVICE

(71) Applicant: Samsung Electronics Co., Ltd., Suwon-si (KR)

(72) Inventors: Teawon KIM, Suwon-si (KR); Jihyun KHO, Suwon-si (KR); Yurim KIM, Suwon-si (KR); Seunghee LEE, Suwon-si (KR); Yong-Suk TAK, Suwon-si (KR)

(21) Appl. No.: 18/947,081

(22) Filed: Nov. 14, 2024

(30) Foreign Application Priority Data
May 17, 2024 (KR) 10-2024-0064772

(51) Int. Cl. H10B 12/00

(52) U.S. Cl. CPC H10B 12/315; H10B 12/482; H10B 12/488

(57) ABSTRACT

A semiconductor memory device including, a bit line disposed on a substrate and extending in a first direction, a channel structure disposed on the bit line and extending in a second direction perpendicular to the first direction, wherein the channel structure includes a first vertical part and a second vertical part spaced apart from the first vertical part in the first direction, a word line disposed between the first vertical part and the second vertical part and extending in the second direction, a gate insulating film disposed between the first vertical part and the word line and between the second vertical part and the word line, a mold pattern disposed on at least one side of the channel structure, and a blocking pattern disposed between the mold pattern and the channel structure.

### CROSS-REFERENCE TO RELATED APPLICATION

This application claims priority under 35 U.S.C. § 119 to Korean Patent Application No. 10-2024-0064772, filed in the Korean Intellectual Property Office on May 17, 2024, the entire contents of which are hereby incorporated by reference.

### BACKGROUND

### Field

The present disclosure relates to a semiconductor memory device.

### Description of Related Art

A semiconductor device is a core component used in an electronic device, and various types of semiconductor devices may be manufactured. For example, a memory device may be mainly used to store and retrieve data, while a non-memory device may be used to control or amplify an electrical signal. The semiconductor device is a core component of an electronic device and plays an important role in various fields including computers, communication equipment, consumer electronics, etc.

With the development of industry, the performance and function requirements of the electronic devices are also increasing. Accordingly, high-performance characteristics of the semiconductor devices are essentially required, and the degree of integration of the semiconductor devices is increasing to meet these requirements. Accordingly, a transistor with a vertical channel has been proposed to improve the degree of integration of semiconductor device.

### SUMMARY

In order to solve one or more problems (e.g., the problems described above and/or other problems not explicitly described herein), the present disclosure provides a semiconductor memory device with improved electrical characteristics and reliability.

According to some embodiments of the present disclosure, by placing the blocking pattern between the mold pattern and the channel structure, it is possible to block the diffusion of hydrogen ions from the mold pattern to the channel structure. Accordingly, the reliability of the semiconductor memory device can be improved.

According to some embodiments of the present disclosure, by placing the blocking pattern between the mold pattern and the landing pad, it is possible to block diffusion of hydrogen ions from the mold pattern to the landing pad. Accordingly, electrical characteristics of the semiconductor memory device can be improved.

According to some embodiments of the present disclosure, a semiconductor memory device includes a bit line disposed on a substrate and extending in a first direction, a channel structure disposed on the bit line and extending in a second direction perpendicular to the first direction, wherein the channel structure includes a first vertical part and a second vertical part spaced apart from the first vertical part in the first direction, a word line disposed between the first vertical part and the second vertical part and extending in the second direction, a gate insulating film disposed between the first vertical part and the word line and between the second vertical part and the word line, a mold pattern disposed on at least one side of the channel structure, and a blocking pattern disposed between the mold pattern and the channel structure.

According to some embodiments of the present disclosure, a semiconductor memory device includes a bit line disposed on a substrate and extending in a first direction, mold patterns aligned on the bit line and spaced apart from each other in the first direction, and extending in a second direction perpendicular to the first direction, a blocking pattern disposed on a side surface of each of the mold patterns, a channel trench defined by the blocking pattern and an upper surface of the bit line, a channel structure disposed in the channel trench, a word line disposed on the channel structure and extending in the second direction, and a gate insulating film disposed between the channel structure and the word line.

According to some embodiments of the present disclosure, a semiconductor memory device includes a bit line disposed on a substrate and extending in a first direction, a channel structure disposed on the bit line and extending in a second direction perpendicular to the first direction, wherein the channel structure includes a first vertical part and a second vertical part spaced apart from the first vertical part in the first direction, a word line disposed between the first vertical part and the second vertical part and extending in the second direction, a gate insulating film disposed between the first vertical part and the word line and between the second vertical part and the word line, a mold pattern disposed on at least one side of the channel structure, a blocking pattern disposed between the mold pattern and the channel structure and extending along a side surface of the mold pattern, a landing pad disposed on each of the first and second vertical parts, and a capacitor structure disposed on the landing pad, wherein a distance from an upper surface of the bit line to an upper surface of the blocking pattern is equal to or greater than a distance from the upper surface of the bit line to an upper surface of the second vertical part.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view provided to explain a semiconductor memory device according to example embodiments of the present disclosure;

FIG. 2 is a cross-sectional view taken along line A-A of FIG. 1;

FIG. 3 is an enlarged view provided to explain a region Q1 of FIG. 2;

FIG. 4 is a cross-sectional view taken along line B-B of FIG. 1;

FIG. 5 is a cross-sectional view taken along line C-C of FIG. 1;

FIG. 6 is a cross-sectional view taken along line D-D of FIG. 1;

FIG. 7 is a diagram illustrating a semiconductor memory device according to example embodiments of the present disclosure;

FIG. 8 is a diagram illustrating a semiconductor memory device according to example embodiments of the present disclosure;

FIG. 9 is a diagram illustrating a semiconductor memory device according to example embodiments of the present disclosure;

FIG. 10 is a diagram illustrating a semiconductor memory device according to example embodiments of the present disclosure; and

FIGS. 11 to 19 are diagrams showing intermediate stages and are provided to explain a method for manufacturing a semiconductor memory device according to example embodiments of the present disclosure.

### DETAILED DESCRIPTION

In the present disclosure, the terms “upper”, “lower”, “upper surface”, and “lower surface” may be used for convenience of description, but aspects are not limited thereto. The terms “upper”, “lower”, “upper surface”, and “lower surface” may be described based on the illustrations in the drawings, and the terms referring to the vertical relationship may change upon vertical rotation of the drawing.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Hereinafter, a semiconductor memory device and a method for manufacturing the same according to some embodiments of the present disclosure will be described in detail with reference to drawings. Like reference characters refer to like elements throughout.

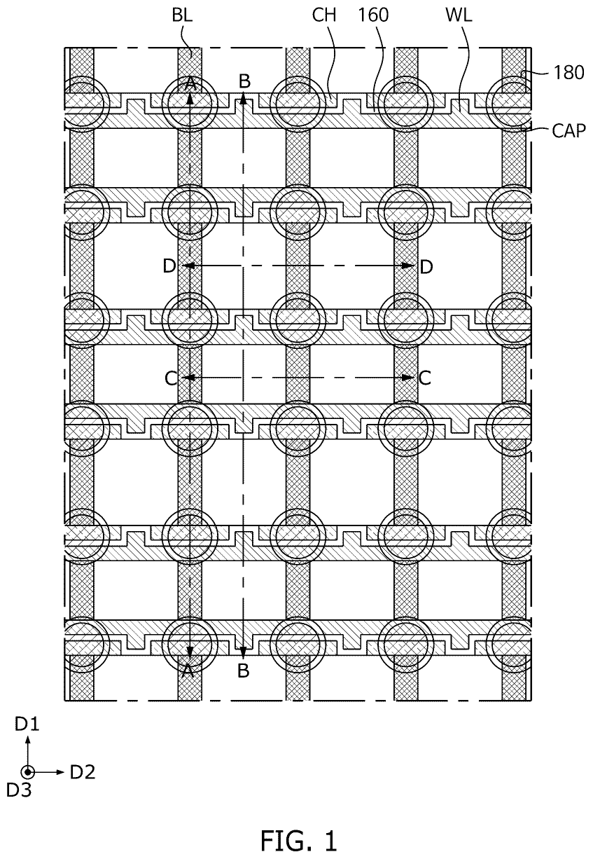

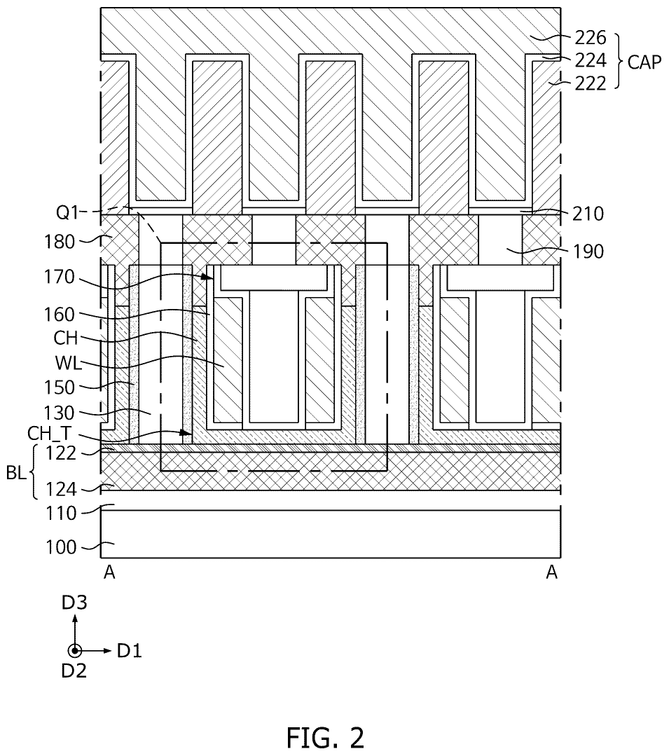

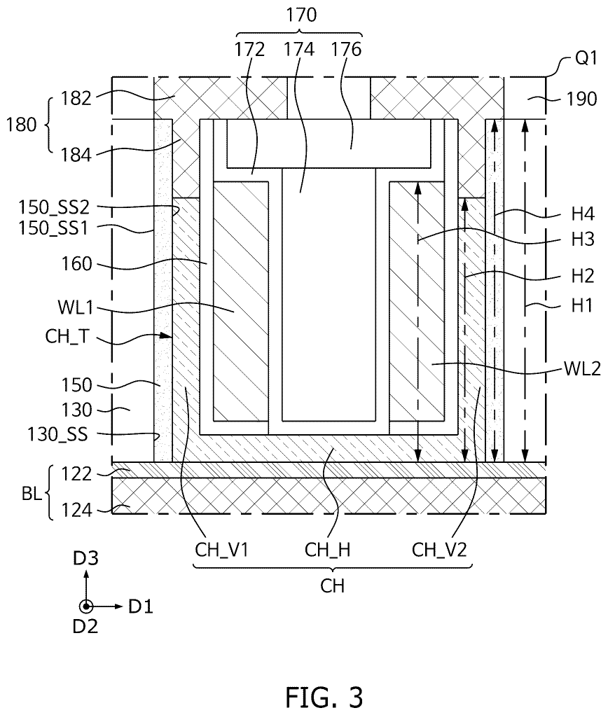

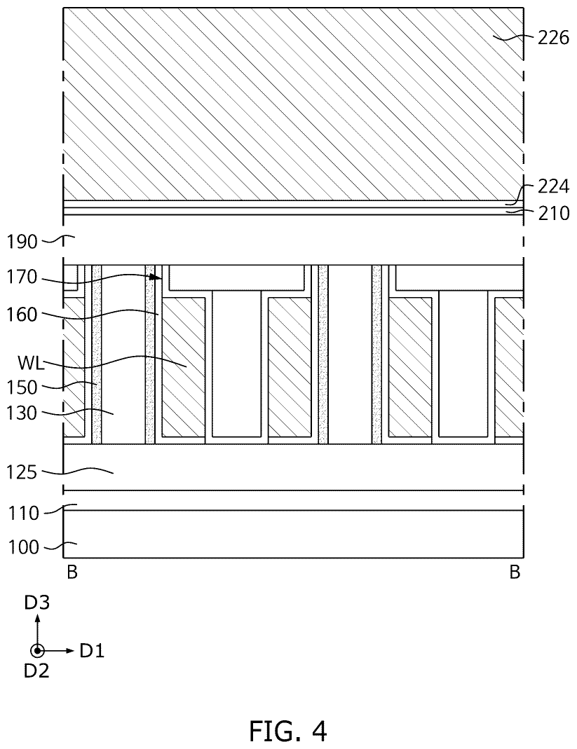

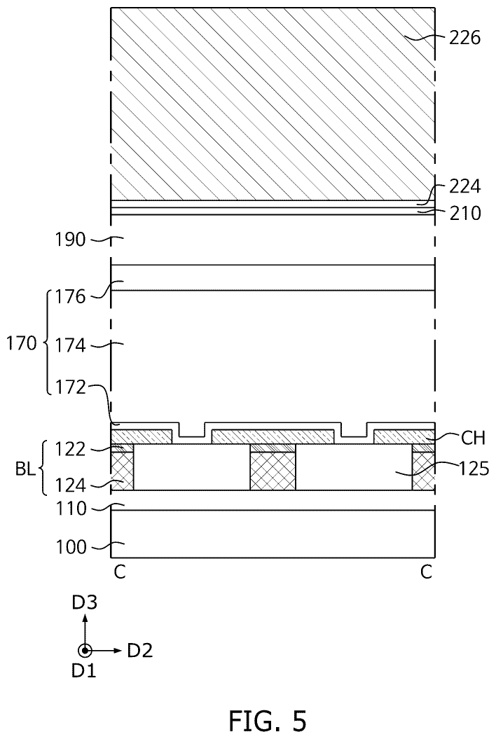

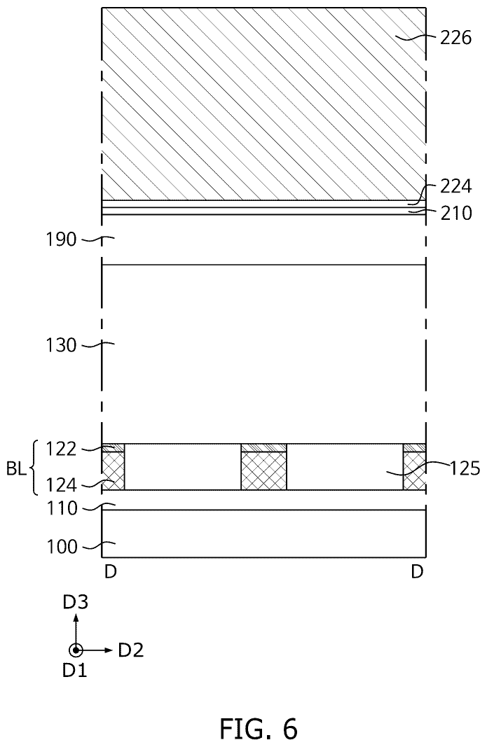

FIG. 1 is a plan view provided to explain a semiconductor memory device according to example embodiments of the present disclosure. FIG. 2 is a cross-sectional view taken along line A-A of FIG. 1. FIG. 3 is an enlarged view provided to explain a region Q1 of FIG. 2. FIG. 4 is a cross-sectional view taken along line B-B of FIG. 1. FIG. 5 is a cross-sectional view taken along line C-C of FIG. 1. FIG. 6 is a cross-sectional view taken along line D-D of FIG. 1. For reference, a dielectric film 224 and an upper electrode 226 of a capacitor structure CAP are omitted and not illustrated in FIG. 1.

The semiconductor memory device according to some embodiments of the present disclosure may include memory cells including a vertical channel transistor (VCT). The vertical channel transistor may refer to a transistor with its channel length extending in a direction perpendicular to an upper surface of the semiconductor substrate.

Referring to FIGS. 1 to 6, the semiconductor memory device according to some embodiments may include a substrate 100, a wiring insulating film 110, bit lines BL, channel structures CH, word lines WL, a bit line insulating film 125, a mold pattern 130, a blocking pattern 150, a gate insulating film 160, a gate separation structure 170, landing pads 180, an interlayer insulating film 190, and a capacitor structure CAP.

The substrate 100 may be a semiconductor substrate. For example, the substrate 100 may be formed of or include silicon (Si), silicon germanium (SiGe), indium antimonide (InSb), lead telluride (PbTe), indium arsenide (InAs), indium phosphide (INP), gallium arsenide (GaAs), gallium antimonide (GaSb), etc. However, aspects are not limited to the above.

In some embodiments, a plurality of transistors connected to the bit line BL may be disposed in the substrate 100. For example, a sensing transistor, a transmission transistor, a driving transistor, etc. may be disposed in the substrate 100. The type of the transistors may vary depending on the layout design of the semiconductor memory device. A region in the substrate 100 where the plurality of transistors are disposed may be referred to as a peripheral circuit area.

The wiring insulating film 110 may be disposed on the substrate 100. In some embodiments, a wiring structure may be disposed in the wiring insulating film 110. The wiring structure may electrically connect the substrate 100 and the bit lines BL. For example, the plurality of transistors disposed in the substrate 100 may be electrically connected to the bit lines BL through the wiring structure.

The bit lines BL may be disposed on the wiring insulating film 110. The bit lines BL may extend lengthwise in a first direction D1 on the wiring insulating film 110. Adjacent bit lines BL of a plurality of bit lines BL may be disposed to be spaced apart from each other in a second direction D2. The second direction D2 may be a direction perpendicular to the first direction D1. In some embodiments, an upper surface of the bit line BL and an upper surface of the bit line insulating film 125 may be disposed on the same plane each other.

The bit lines BL may include a conductive layer 124 and a contact layer 122. The contact layer 122 may be disposed on the conductive layer 124. For example, a lower surface of the contact layer 122 may contact an upper surface of the conductive layer 124. In example embodiments, the conductive layer 124 may include at least one of doped polysilicon, metal (e.g., Al, Cu, Ti, Ta, Ru, W, Mo, Pt, Ni, Co), conductive metal nitride (e.g., TiN, TaN, WN, NON, TiAlN, TiSiN, TaSiN, RuTiN), conductive metal silicide or conductive metal oxide (e.g., PtO, RuO₂, IrO₂, SrRuO₃ (SRO), (Ba,Sr)RuO₃ (BSRO), CaRuO₃ (CRO), LSCo), but aspects are not limited thereto.

For example, the contact layer 122 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbon nitride (WCN), zirconium (Zr), zirconium nitride (ZrN), vanadium (V), vanadium nitride (VN), niobium (Nb), niobium nitride (Nb), platinum (Pt), iridium (Ir), rhodium (Rh), and a two-dimensional (2D) material.

In some embodiments, the contact layer 122 and the conductive layer 124 may include a 2D semiconductor material. For example, the 2D material may include a 2D allotrope or a 2D compound, and may include at least one of graphene, carbon nanotubes, molybdenum disulfide (MoS₂), molybdenum diselenide (MoSe₂), tungsten diselenide (WSe₂), tungsten disulfide (WS₂), for example, but aspects are not limited thereto. That is, the 2D materials described above are merely a list of some examples, and the 2D materials that may be included in the semiconductor memory device of the present disclosure are not limited to the materials mentioned above.

The mold pattern 130 may be disposed on the upper surface of the bit line BL and the upper surface of the bit line insulating film 125. The mold pattern 130 may extend lengthwise in the second direction D2. The mold patterns 130 may be aligned and spaced apart from each other in the first direction D1.

The mold pattern 130 may be formed of or include an insulating material. For example, the mold pattern 130 may include at least one of silicon oxide, silicon nitride, silicon oxynitride, and a low-k insulating material.

The blocking pattern 150 may be disposed on the upper surface of the bit line BL, the upper surface of the bit line insulating film 125, and a side surface 130_SS of the mold pattern 130. The blocking pattern 150 may extend along the side surface 130_SS of the mold pattern 130 in the second direction D2. The blocking pattern 150 may overlap the mold pattern 130 in the first direction D1. The blocking pattern 150 may not overlap the mold pattern 130 in a third direction D3. The third direction D3 may be a direction perpendicular to the upper surface of the bit line BL. The third direction D3 may be perpendicular to each of the first and second directions D1 and D2.

The blocking pattern 150 may be disposed between the mold pattern 130 and the channel structure CH. A first side surface 150_SS1 of the blocking pattern 150 may be in contact with the side surface 130_SS of the mold pattern 130. A second side surface 150_SS2 of the blocking pattern 150 may be in contact with the channel structure CH. The first side surface 150_SS1 of the blocking pattern 150 may be opposite to the second side surface 150_SS2 in the first direction D1.

For example, the blocking pattern 150 may be formed of or include any one of aluminum oxide, hafnium oxide, zirconium oxide, and silicon nitride.

A channel trench CH_T may be disposed on the upper surface of the bit line BL. A bottom surface of the channel trench CH_T may be defined as the upper surface of the bit line BL and the upper surface of the bit line insulating film 125. Both side surfaces of the channel trench CH_T may be defined by two blocking patterns 150 facing each other in the first direction D1. The channel trench CH_T may extend lengthwise in the second direction D2. The channel trenches CH_T may be spaced apart from each other in the first direction D1 and the second direction D2. The channel trench CH_T may expose the upper surface of the bit line BL.

The channel structure CH may be disposed on the upper surface of the bit line BL. The channel structure CH may be connected to the bit line BL. The channel structures CH disposed on one bit line BL may be spaced apart from each other in the first direction D1.

The channel structure CH may be disposed in the channel trench CH_T. The channel structure CH may extend along a sidewall and a bottom surface of the channel trench CH_T. From a cross-sectional point of view, the channel structure CH may have an approximately “U” shape.

The channel structure CH may include a first vertical part CH_V1, a second vertical part CH_V2, and a horizontal part CH_H.

Each of the first vertical part CH_V1 and the second vertical part CH_V2 may be disposed on the second side surface 150_SS2 of the blocking pattern 150. Each of the first vertical part CH_V1 and the second vertical part CH_V2 may be in contact with the second side surface 150_SS2 of the blocking pattern 150. Each of the first vertical part CH_V1 and the second vertical part CH_V2 may extend in the third direction D3. The first vertical part CH_V1 may extend from one end of the horizontal part CH_H in the third direction D3, and the second vertical part CH_V2 may extend from the other end of the horizontal part CH_H in the third direction D3. The first vertical part CH_V1 and the second vertical part CH_V2 may be spaced apart from each other in the first direction D1.

The horizontal part CH_H may be disposed along the upper surface of the bit line BL. The horizontal part CH_H may connect the first vertical part CH_V1 and the second vertical part CH_V2. However, aspects are not limited thereto. Unlike the illustration, the horizontal part CH_H may be separated into two parts. For example, one separated part of the horizontal part CH_H may be connected to the first vertical part CH_V1, and the other separated part of the horizontal part CH_H may be connected to the second vertical part CH_V2. The gate separation structure 170 may be disposed between the separated horizontal parts CH_H.

The channel structure CH may include an oxide semiconductor. For example, the oxide semiconductor may include at least one of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O and InₓGa_{y}O, but aspects are not limited thereto. For example, the channel structure CH may include an indium gallium zinc oxide (IGZO). The channel structure CH may include a single layer or multiple layers of an oxide semiconductor. The channel structure CH may include an amorphous, crystalline, or polycrystalline oxide semiconductor.

In some embodiments, the channel structure CH may have a bandgap energy greater than that of silicon. For example, the channel structure CH may have a bandgap energy of about 1.5 eV to 5.6 eV. For example, the channel structure CH may have optimal channel performance when it has a bandgap energy of about 2.0 eV to 4.0 eV. For example, the channel structure CH may be polycrystalline or amorphous, but aspects are not limited thereto.

In some embodiments, the channel structure CH may include a 2D semiconductor material. For example, the 2D semiconductor material may include graphene, carbon nanotube, or a combination thereof.

In some embodiments, a distance H1 from the upper surface of the bit line BL to the upper surface of the mold pattern 130 may be equal to a distance H4 from the upper surface of the bit line BL to an upper surface of the blocking pattern 150. In other words, the upper surface of the mold pattern 130 and the upper surface of the blocking pattern 150 may be disposed on the same plane each other. For example, upper surfaces of the mold pattern 130 and the blocking pattern 150 may be coplanar, and lower surfaces of the mold pattern 130 and the blocking pattern 150 may be coplanar. The first side surface 150_SS1 of the blocking pattern 150 may completely cover the side surface 130_SS of the mold pattern 130. Accordingly, diffusion of hydrogen ions from the side surface 130_SS of the mold pattern 130 can be blocked by the blocking pattern 150.

In some embodiments, the uppermost portion of the channel structure CH may be disposed lower than the upper surface of the mold pattern 130. For example, a distance H2 from the upper surface of the bit line BL to an upper surface of the second vertical part CH_V2 may be less than the distance H1 from the upper surface of the bit line BL to the upper surface of the mold pattern 130.

In some embodiments, the upper surface of the blocking pattern 150 may be disposed higher than the upper surface of the first vertical part CH_V1 and the upper surface of the second vertical part CH_V2. For example, the distance H4 from the upper surface of the bit line BL to the upper surface of the blocking pattern 150 may be greater than the distance H2 from the upper surface of the bit line BL to the second vertical part CH_V2.

The blocking pattern 150 may completely cover one side surface of the first vertical part CH_V1 and one side surface of the second vertical part CH_V2. With the blocking pattern 150 having such a configuration, the diffusion of hydrogen ions from the mold pattern 130 to the channel structure CH can be prevented. That is, the blocking pattern 150 may prevent the electrical characteristics of the channel structure CH from deteriorating. Accordingly, electrical characteristics and reliability of the semiconductor memory device can be improved.

The word line WL may be disposed on the channel structure CH. The word line WL may intersect the bit line BL. The word line WL may extend in the second direction D2. The word lines WL may be disposed to be spaced apart from each other in the first direction D1. The word line WL may include a first word line WL1 and a second word line WL2.

Each of the first word line WL1 and the second word line WL2 may be disposed on the channel structure CH. Each of the first word line WL1 and the second word line WL2 may be disposed between the first vertical part CH_V1 and the second vertical part CH_V2. The first word line WL1 may be disposed on one side of the horizontal part CH_H and the first vertical part CH_V1. The second word line WL2 may be disposed on one side of the horizontal part CH_H and the second vertical part CH_V2. The first word line WL1 and the second word line WL2 may be disposed to be spaced apart from each other in the first direction D1.

The width of the first word line WL1 may not be constant in the first direction D1. For example, a portion of the first word line WL1 disposed on the channel structure CH may have a smaller width in the first direction D1 than a portion of the first word line WL1 not disposed on the channel structure CH. For example, the portion of the first word line WL1 disposed between the channel structures CH may have a smaller width in the first direction D1 than the portion of the first word line WL1 not disposed between the channel structures CH. The second word line WL2 may be configured with the same or similar width as the first word line WL1 in the first direction D1.

For example, the word line WL may include at least one of doped polysilicon, metal (e.g., Al, Cu, Ti, Ta, Ru, W, Mo, Pt, Ni, Co), conductive metal nitride (e.g., TiN, TaN, WN, NbN, TiAlN, TiSiN, TaSiN, RuTiN), conductive metal silicide or conductive metal oxide (e.g., PtO, RuO₂, IrO₂, SrRuO₃ (SRO), (Ba,Sr) RuO₃ (BSRO), CaRuO₃ (CRO), LSCo), but aspects are not limited thereto. The word line WL may include a single layer of each of the materials described above or multiple layers of the materials.

In some embodiments, the word line WL may include a 2D semiconductor material. For example, the 2D semiconductor material may include graphene, carbon nanotube, or a combination thereof.

In some embodiments, an upper surface of the first word line WL1 may be disposed higher than the upper surface of the first vertical part CH_V1. An upper surface of the second word line WL2 may be disposed higher than an upper surface of the second vertical part CH_V2. For example, a distance H3 from the upper surface of the bit line BL to the upper surface of the second word line WL2 may be greater than the distance H2 from the upper surface of the bit line BL to the upper surface of the second vertical part CH_V2.

The gate insulating film 160 may be disposed between the word line WL and the channel structure CH. For example, the gate insulating film 160 may be disposed between the first word line WL1 and the first vertical part CH_V1 and between the second word line WL2 and the second vertical part CH_V2, respectively. The gate insulating film 160 may extend parallel to the first word line WL1 and the second word line WL2 in the second direction D2. The first word line WL1 and the second word line WL2 may not be in contact with the channel structure CH due to the presence of the gate insulating film 160. For example, the first word line WL1 and the second word line WL2 may be electrically separated from the channel structure CH by the gate insulating film 160.

A portion of the gate insulating film 160 may protrude in the third direction D3 further than the upper surface of the first word line WL1 and the upper surface of the second word line WL2. For example, the uppermost portion of the gate insulating film 160 may be disposed higher than the upper surface of the first word line WL1 and the upper surface of the second word line WL2.

A distance from the upper surface of the bit line BL to the uppermost portion of the gate insulating film 160 may be greater than the distance H2 from the upper surface of the bit line BL to the upper surface of the second vertical part CH_V2 of the channel structure CH. The distance from the upper surface of the bit line BL to the uppermost portion of the gate insulating film 160 may be greater than the distance H3 from the upper surface of the bit line BL to the upper surface of the second word line WL2.

The gate insulating film 160 may include at least one of silicon oxide, silicon oxynitride, and a high-k material having a dielectric constant higher than that of the silicon oxide. The high-k material may include a metal oxide or a metal oxynitride. For example, the high-k material available as the gate insulating film 160 may include at least one of HfO₂, HfSiO, HfSiON, HfTaO, HfTiO, HfZrO, ZrO₂ and Al₂O₃, but aspects are not limited thereto.

The gate separation structure 170 may be disposed on the bit line BL and the bit line insulating film 125. The gate separation structure 170 may be disposed in the channel trench CH_T. The gate separation structure 170 may be disposed on the channel structure CH. In the semiconductor memory device according to some embodiments, the gate separation structure 170 may be in contact with the channel structure CH. The gate separation structure 170 may be in contact with the horizontal part CH_H. The gate separation structure 170 may be spaced apart from the bit line BL in the third direction D3.

The gate separation structure 170 may be disposed between the first word line WL1 and the second word line WL2 to separate the first word line WL1 and the second word line WL2 in the first direction D1. The gate separation structure 170 may extend in the second direction D2 between the first word line WL1 and the second word line WL2. The gate separation structure 170 may contact the first word line WL1, the second word line WL2, and the gate insulating film 160.

The first word line WL1 may be disposed between the gate separation structure 170 and the first vertical part CH_V1. The second word line WL2 may be disposed between the gate separation structure 170 and the second vertical part CH_V2.

The gate separation structure 170 may include a horizontal part and a protrusion part. The protrusion part of the gate separation structure 170 may protrude from the horizontal part of the gate separation structure 170 toward the bit line BL in the third direction D3. The protrusion part of the gate separation structure 170 may be closer to the bit line BL than the horizontal part of the gate separation structure 170. The horizontal part of the gate separation structure 170 may be disposed on the upper surfaces of the first and second word lines WL1 and WL2. From a cross-sectional point of view, the gate separation structure 170 may have a “T” shape.

The gate separation structure 170 may include a gate separation liner film 172, a gate separation filling film 174, and a gate separation capping film 176. The gate separation liner film 172 may extend along the upper surface and outer surface of the first word line WL1 and the upper surface and outer surface of the second word line WL2. The gate separation liner film 172 may extend along the horizontal part CH_H of the channel structure CH. The gate separation liner film 172 may be in contact with the horizontal part CH_H. The gate separation liner film 172 may extend along the gate insulating film 160 that protrudes further than the upper surface of the first word line WL1 and the upper surface of the second word line WL2. Unlike the illustration, the gate separation liner film 172 may not extend along the gate insulating film 160 that protrudes further than the upper surface of the first word line WL1 and the upper surface of the second word line WL2.

The gate separation filling film 174 may be disposed on the gate separation liner film 172. For example, the gate separation filling film 174 may contact side and upper surfaces of the gate separation liner film 172. The gate separation capping film 176 may be disposed on the gate separation filling film 174. For example, the gate separation capping film 176 may contact an upper surface of the gate separation filling film 174 and upper and side surfaces of the gate separation liner film 172. Upper surfaces of the gate separation capping film 176 and the gate separation liner film 172 may be coplanar. An uppermost surface of the gate separation filling film 174 may be at a lower vertical level than uppermost surfaces of the gate separation filling film 174 and the gate separation liner film 172. Each of the gate separation liner film 172, the gate separation filling film 174, and the gate separation capping film 176 may be formed of an insulating material. Unlike the illustration, the gate separation structure 170 may be a single layer.

In some embodiments, the upper surface of the gate separation structure 170 may be disposed on the same plane with the upper surface of the mold pattern 130. For example, a distance from the upper surface of the bit line BL to the upper surface of the gate separation structure 170 may be equal to the distance H1 from the upper surface of the bit line BL to the upper surface of the mold pattern 130. However, aspects are not limited thereto.

The landing pad 180 may be disposed on the blocking pattern 150, the channel structure CH, and the gate separation structure 170. The landing pad 180 may be in contact with the blocking pattern 150 and the channel structure CH. The landing pad 180 may be electrically connected to the channel structure CH.

The landing pad 180 may include a pad part 182 and a protrusion part 184. The pad part 182 may be disposed on the gate separation structure 170. When viewed in a plan view, the pad part 182 may have various shapes such as a circle, an ellipse, a rectangle, a square, a rhombus, and a hexagon. When viewed in a plan view, the pad part 182 may be disposed in various forms such as a matrix form, a zigzag form, and a honeycomb form along the first and second directions D1 and D2. The upper surface of the pad part 182 may be laid flush with an upper surface of the interlayer insulating film 190, but aspects are not limited thereto.

The interlayer insulating film 190 may be disposed on the mold pattern 130 and the gate separation structure 170. The interlayer insulating film 190 may be disposed between the adjacent pad parts 182, and may contact side surfaces of the adjacent pad parts 182. The interlayer insulating film 190 may overlap the pad part 182 in the first direction D1. The upper surface of the interlayer insulating film 190 and the upper surface of the pad part 182 may be disposed on the same plane each other. The interlayer insulating film 190 may include an insulating material.

The protrusion part 184 may protrude from the pad part 182 toward the bit line BL in the third direction D3. The protrusion part 184 may be in contact with the channel structure CH. For example, the protrusion part 184 may be in contact with each of the first vertical part CH_V1 and the second vertical part CH_V2. A portion of the protrusion part 184 may overlap each of the first word line WL1 and the second word line WL2 in the first direction D1.

In some embodiments, the protrusion part 184 may be disposed between the blocking pattern 150 and the gate insulating film 160. For example, the protrusion part 184 may be disposed between the blocking pattern 150 and the gate insulating film 160 which are disposed in an upper portion of the channel structure CH. The protrusion part 184 may contact side surfaces of the blocking pattern 150 and the gate insulating film 160. The blocking pattern 150 may be disposed between the mold pattern 130 and the protrusion part 184.

The landing pad 180 may be spaced apart from the mold pattern 130 by the blocking pattern 150. The landing pad 104 may not be in contact with the mold pattern 130. The blocking pattern 150 may prevent the diffusion of hydrogen ions from the mold pattern 130 to the landing pad 180. Accordingly, reliability of the landing pad 180 can be improved.

The landing pad 180 may be formed of a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but aspects are not limited thereto.

An etching stop film 210 may be disposed on the landing pad 180 and the interlayer insulating film 190. The etching stop film 210 may expose the landing pad 180.

The capacitor structure CAP may be disposed on the landing pad 180 and the interlayer insulating film 190. The capacitor structure CAP may store a signal received from a transistor in a peripheral circuit structure (e.g., row and column decoders, sense amplifier, etc.) of the semiconductor memory device. The capacitor structure CAP may be used as a data storage element electrically connected to the transistor. For example, the capacitor structure CAP may store electric charges under the control of the transistor.

The capacitor structure CAP may include a lower electrode 222, the dielectric film 224, and the upper electrode 226.

The lower electrode 222 may be disposed on the landing pad 180. The lower electrode 222 may be electrically connected to the landing pad 180. A portion of the lower electrode 222 may be disposed in the etching stop film 210. For example, the lower electrode 222 may extend through the etching stop film 210 and be connected to the landing pad 180. For example, the lower electrode 222 may extend through the etching stop film 210.

For example, the lower electrode 222 may include at least one of a conductive metal material (cobalt (Co), titanium (Ti), nickel (Ni), tungsten (W), molybdenum (Mo), etc.), a metal nitride (titanium nitride (TiN), titanium silicon nitride (TiSiN), titanium aluminum nitride (TiAlN), tantalum aluminum nitride (TaAlN), tungsten nitride (WN), etc.), a noble metal material (platinum (Pt), ruthenium (Ru), iridium (Ir), etc.), a conductive oxide film (PtO, RuO₂, IrO₂, SrRuO₃ (SRO), (Ba,Sr) RuO₃ (BSRO), CaRuO₃ (CRO), LSCO, etc.), and a metal silicide film. However, aspects are not limited thereto.

Although not illustrated, in some embodiments, at least one supporter may be disposed between the lower electrodes 222. The supporter may support the lower electrode 222.

The dielectric film 224 may be disposed on the lower electrode 222. The dielectric film 224 may extend along the profile of the lower electrode 222. The dielectric film 224 may contact upper and side surfaces of the lower electrode 222 and an upper surface of the etching stop film 210. For example, the dielectric film 224 may include a high dielectric constant material including a silicon oxide, a silicon nitride, a silicon oxynitride, and a metal. Although it is illustrated that the dielectric film 224 is a single film, it is only for convenience of description, and aspects are not limited thereto. Unlike the illustration, the dielectric film 224 may include a plurality of films.

The upper electrode 226 may be disposed on the dielectric film 224. The upper electrode 226 may contact the dielectric film 224. The upper electrode 226 may fill an empty space between the lower electrodes 222. For example, the upper electrode 226 may include at least one of an element semiconductor material film and a compound semiconductor material film. The upper electrode 226 may include a doped n-type or p-type impurity.

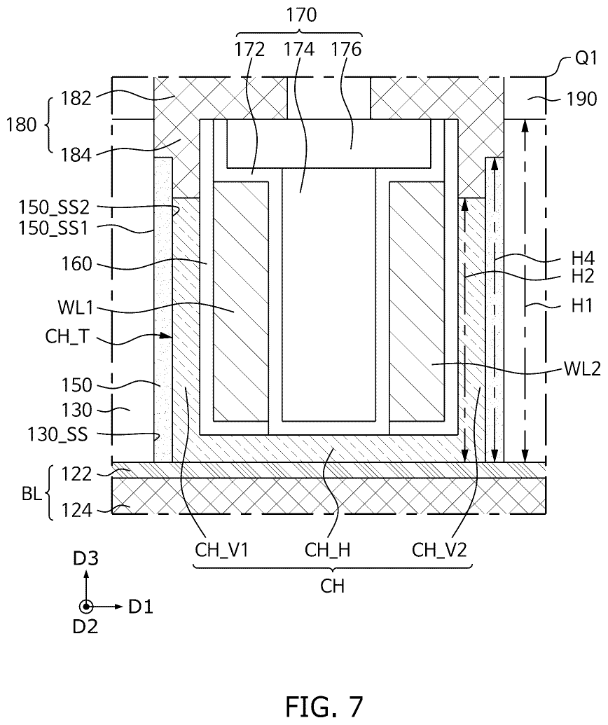

FIG. 7 is a diagram illustrating a semiconductor memory device according to example embodiments of the present disclosure. For reference, FIG. 7 may correspond to an enlarged view of the region Q1 of FIG. 2. For convenience of description, different configurations from those described in FIGS. 1 to 6 will be mainly described.

Referring to FIG. 7, in the semiconductor memory device according to some embodiments, the upper surface of the blocking pattern 150 may be disposed lower than the upper surface of the mold pattern 130. For example, the distance H4 from the upper surface of the bit line BL to the upper surface of the blocking pattern 150 may be less than the distance H1 from the upper surface of the bit line BL to the upper surface of the mold pattern 130.

The upper surface of the blocking pattern 150 may be disposed higher than the uppermost portion of the channel structure CH. For example, the distance H4 from the upper surface of the bit line BL to the upper surface of the blocking pattern 150 may be greater than the distance H2 from the upper surface of the bit line BL to the upper surface of the second vertical part CH_V2. An outer surface of each of the first vertical part CH_V1 and the second vertical part CH_V2 may be in contact with the second side surface 150_SS2 of the blocking pattern 150. The blocking pattern 150 may completely cover the outer surface of each of the first vertical part CH_V1 and the second vertical part CH_V2. For example, the blocking pattern 150 may contact the entire outer surface of each of the first vertical part CH_V1 and the second vertical part CH_V2. The blocking pattern 150 may block the diffusion of hydrogen ions to the first vertical part CH_V1 and the second vertical part CH_V2.

The landing pad 180 may include the pad part 182 and the protrusion part 184. The pad part 182 may be disposed on the gate separation structure 170. The protrusion part 184 may protrude from the pad part 182 toward the bit line BL in the third direction D3. The protrusion part 184 may be disposed between the mold pattern 130 and the gate insulating film 160 and between the blocking pattern 150 and the gate insulating film 160. From a cross-sectional point of view, the protrusion part 184 may have a stepped part on the blocking pattern 150. The protrusion part 184 may be in contact with the side surface 130_SS of the mold pattern 130 and the second side surface 150_SS2 of the blocking pattern 150. The protrusion part 184 may contact an upper surface of the blocking pattern 150 and a side surface of the gate insulating film 160.

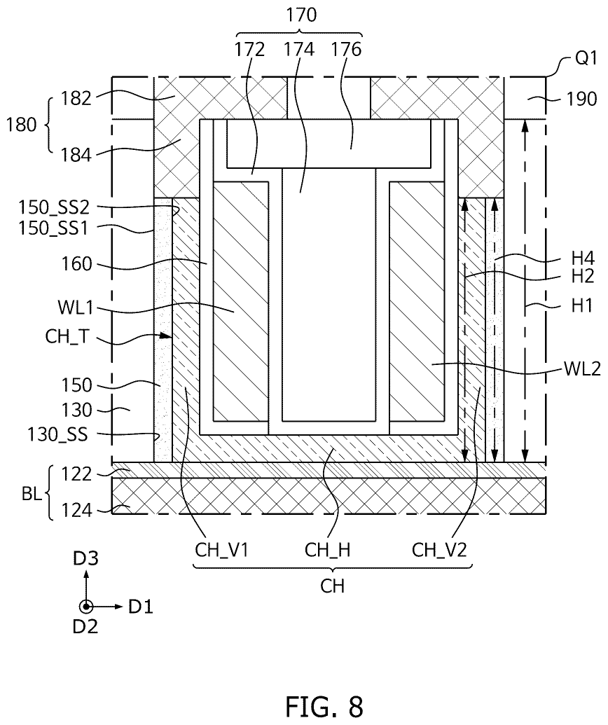

FIG. 8 is a diagram illustrating a semiconductor memory device according to example embodiments of the present disclosure. For reference, FIG. 8 may correspond to an enlarged view of the region Q1 of FIG. 2. For convenience of description, different configurations from those described in FIGS. 1 to 6 will be mainly described.

Referring to FIG. 8, in the semiconductor memory device according to some embodiments, the upper surface of the blocking pattern 150 may be disposed on the same plane as the upper surface of the channel structure CH. The upper surface of the channel structure CH may refer to the upper surface of the first vertical part CH_V1 and the upper surface of the second vertical part CH_V2. For example, the distance H4 from the upper surface of the bit line BL to the upper surface of the blocking pattern 150 may be equal to the distance H2 from the upper surface of the bit line BL to the upper surface of the second vertical part CH_V2. The blocking pattern 150 may completely cover the outer surface of each of the first vertical part CH_V1 and the second vertical part CH_V2. The blocking pattern 150 may block the diffusion of hydrogen ions to the first vertical part CH_V1 and the second vertical part CH_V2.

The upper surface of the blocking pattern 150 may be disposed lower than the upper surface of the mold pattern 130. For example, the distance H4 from the upper surface of the bit line BL to the upper surface of the blocking pattern 150 may be less than the distance H1 from the upper surface of the bit line BL to the upper surface of the mold pattern 130.

The landing pad 180 may include the pad part 182 and the protrusion part 184. The pad part 182 may be disposed on the gate separation structure 170. The protrusion part 184 may protrude from the pad part 182 toward the bit line BL in the third direction D3. The protrusion part 184 may be disposed between the mold pattern 130 and the gate insulating film 160. The protrusion part 184 may be in contact with the upper surface of the channel structure CH and the upper surface of the blocking pattern 150.

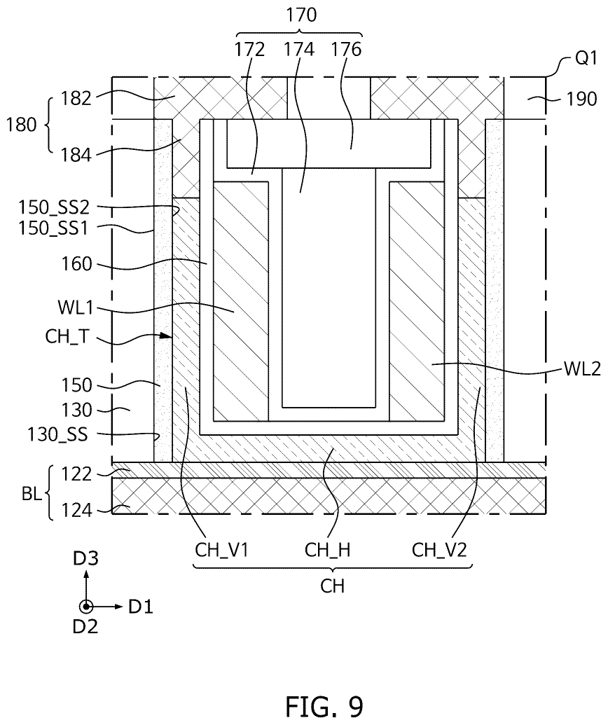

FIG. 9 is a diagram illustrating a semiconductor memory device according to example embodiments of the present disclosure. For reference, FIG. 9 may correspond to an enlarged view of the region Q1 of FIG. 2. For convenience of description, different configurations from those described in FIGS. 1 to 6 will be mainly described.

Referring to FIG. 9, in the semiconductor memory device according to some embodiments, the gate insulating film 160 may be disposed between the channel structure CH and the first word line WL1 and between the channel structure CH and the second word line WL2.

Specifically, the gate insulating film 160 may extend along an inner surface of the first vertical part CH_V1, an upper surface of the horizontal part CH_H, and an inner surface of the second vertical part CH_V2. The inner surface of the first vertical part CH_V1 may be a surface facing the first word line WL1, and the inner surface of the second vertical part CH_V2 may be a surface facing the second word line WL2. The gate insulating film 160 disposed on the inner surfaces of the first vertical part CH_V1 and the gate insulating film 160 disposed on the inner surface of the second vertical part CH_V2 may be connected to the upper surface of the horizontal part CH_H. For example, the gate insulating film 160 may contact the upper surface of the horizontal part CH_H.

The gate separation structure 170 may be disposed on the first word line WL1, the second word line WL2, and the gate insulating film 160. The gate separation structure 170 may include a gate separation liner film 172, a gate separation filling film 174, and a gate separation capping film 176. The gate separation liner film 172 may be in contact with the gate insulating film 160.

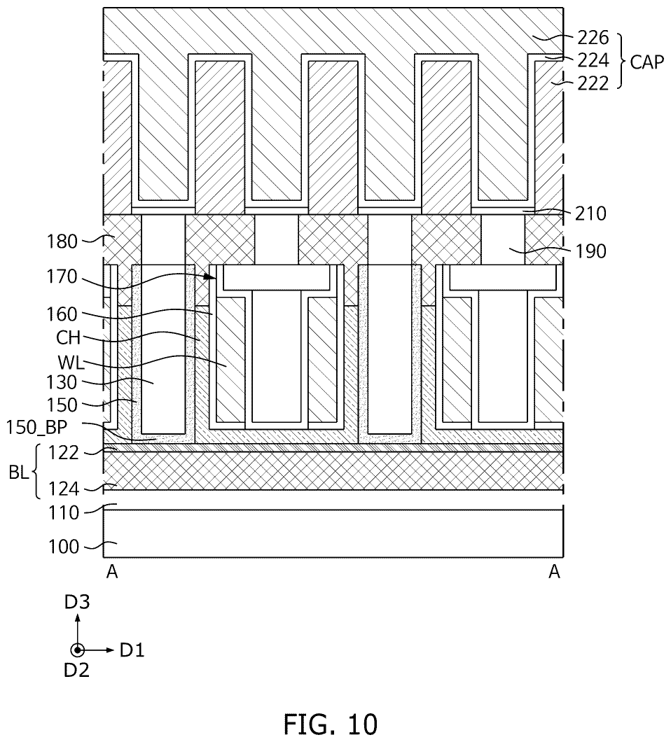

FIG. 10 is a diagram illustrating a semiconductor memory device according to example embodiments of the present disclosure. For reference, FIG. 10 may correspond to a cross-sectional view taken along line A-A of FIG. 1. For convenience of description, different configurations from those described in FIGS. 1 to 6 will be mainly described.

Referring to FIG. 10, in the semiconductor memory device according to some embodiments, the blocking pattern 150 may include a bottom part 150_BP disposed between the upper surface of the bit line BL and the mold pattern 130.

The blocking pattern 150 may be disposed on the upper surface of the bit line BL, the upper surface of the bit line insulating film 125, and the side surface 130_SS and a lower surface of the mold pattern 130. For example, the bottom part 150_BP of the blocking pattern 150 may be disposed between the lower surface of the mold pattern 130 and the upper surface of the bit line BL. The bottom part 150_BP of the blocking pattern 150 may contact the lower surface of the mold pattern 130 and the upper surface of the bit line BL. The blocking pattern 150 disposed on both side surfaces of the mold pattern 130 may be connected to the bottom part 150_BP. From a cross-sectional point of view, the blocking pattern 150 may have an approximately “U” shape.

The mold pattern 130 may not be in contact with the bit line BL due to the presence of the bottom part 150_BP of the blocking pattern 150. The mold pattern 130 may be spaced apart from the bit line BL in the third direction D3. The bottom part 150_BP of the blocking pattern 150 may block the diffusion of hydrogen ions from the mold pattern 130 to the bit line BL.

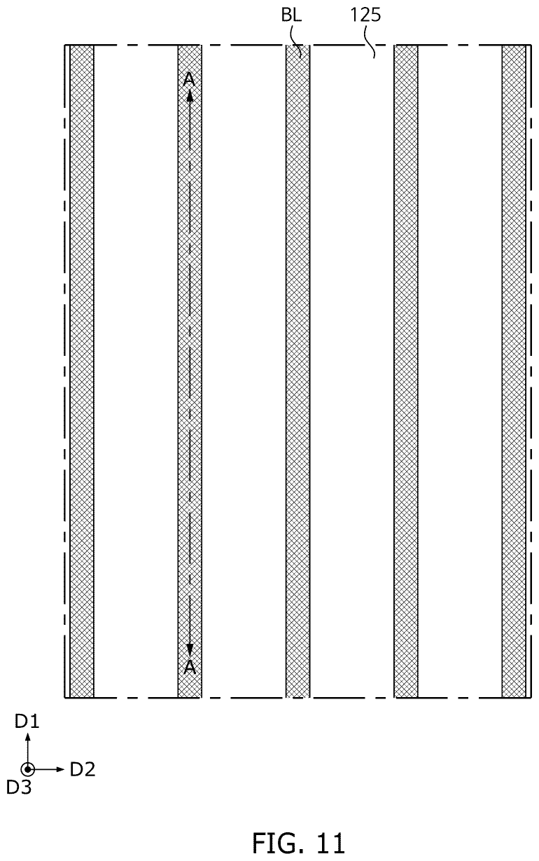

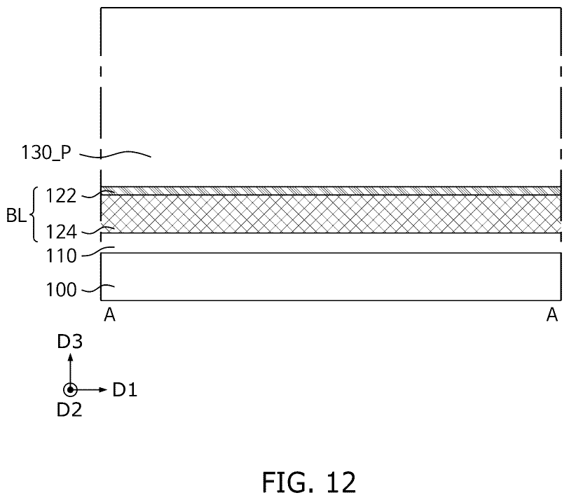

FIGS. 11 to 19 are diagrams showing intermediate stages, and are provided to explain a method for manufacturing a semiconductor memory device according to example embodiments of the present disclosure. For reference, FIG. 11 is a plan view provided to explain a method for manufacturing a semiconductor memory device. FIGS. 12 to 19 may correspond to a cross-sectional view taken along line A-A of FIG. 11.

Referring to FIGS. 11 and 12, the wiring insulating film 110, the bit line BL, and the bit line insulating film 125 may be formed on the substrate 100.

The substrate 100 may be a semiconductor substrate. For example, the substrate 100 may include silicon (Si), silicon germanium (SiGe), indium antimonide (InSb), lead telluride (PbTe), indium arsenide (InAs), indium phosphide (INP), gallium arsenide (GaAs), gallium antimonide (GaSb), etc. However, aspects are not limited thereto.

In some embodiments, a plurality of transistors connected to the bit line BL may be disposed in the substrate 100. For example, a sensing transistor, a transmission transistor, a driving transistor, etc. may be disposed in the substrate 100. The type of the transistors may vary depending on the layout design of the semiconductor memory device. A region in the substrate 100 where the plurality of transistors are disposed may be referred to as a peripheral circuit area.

The wiring insulating film 110 may be formed on the substrate 100. The bit line BL and the bit line insulating film 125 may be formed on the wiring insulating film 110. The bit line BL may extend lengthwise in the first direction D1 on the wiring insulating film 110. Adjacent bit lines BL may be disposed to be spaced apart from each other in the second direction D2. The bit line insulating film 125 may be disposed between adjacent bit lines BL.

A pre-mold insulating film 130_P may be formed on the upper surface of the bit line BL and the upper surface of the bit line insulating film 125. The pre-mold insulating film 130_P may cover the bit line BL and the bit line insulating film 125.

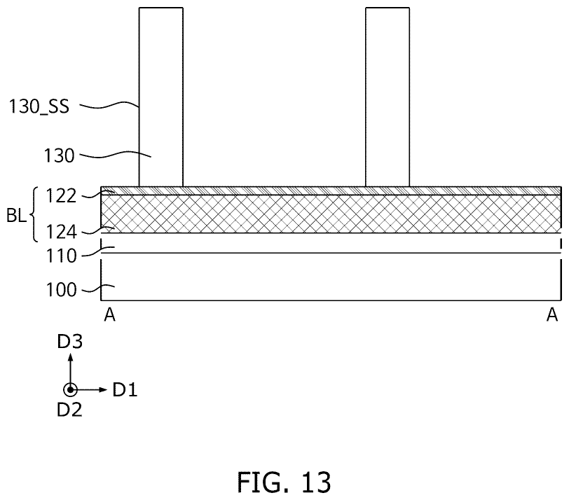

Referring to FIGS. 12 and 13, the pre-mold insulating film 130_P may be etched to form the mold pattern 130.

Specifically, a hard mask pattern may be formed on the pre-mold insulating film 130_P. The hard mask pattern may expose a portion of the pre-mold insulating film 130_P. The pre-mold insulating film 130_P exposed to the hard mask pattern may be etched to form the mold pattern 130. The mold pattern 130 may extend in the second direction D2. The mold patterns 130 may be disposed to be spaced apart from each other in the first direction D1.

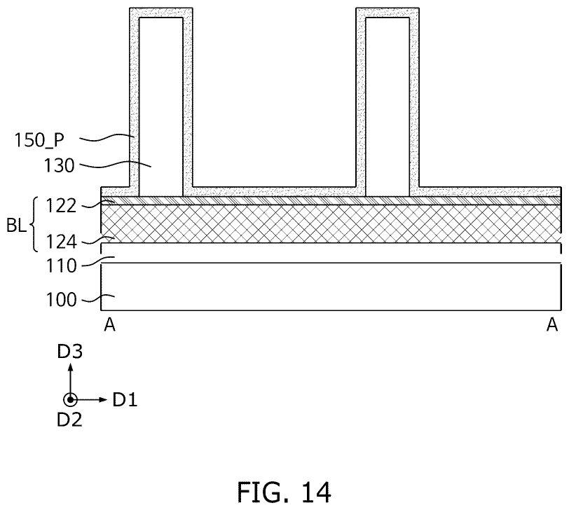

Referring to FIGS. 13 and 14, a pre-blocking pattern 150_P may be formed on the bit line BL, the bit line insulating film, and the mold pattern 130.

The pre-blocking pattern 150_P may be formed along the side surface 130_SS and the upper surface of the mold pattern 130, the upper surface of the bit line BL, and the upper surface of the bit line insulating film (e.g., bit line insulating film 125). The pre-blocking pattern 150_P may cover the upper surface of the bit line BL and the upper surface of the bit line insulating film (e.g., bit line insulating film 125).

For example, the pre-blocking pattern 150_P may be formed by any one of physical vapor deposition (PVD), chemical vapor deposition (CVD), and atomic layer deposition (ALD). However, aspects are not limited thereto.

For example, the pre-blocking pattern 150_P may be formed of or include any one of aluminum oxide, hafnium oxide, zirconium oxide, and silicon nitride.

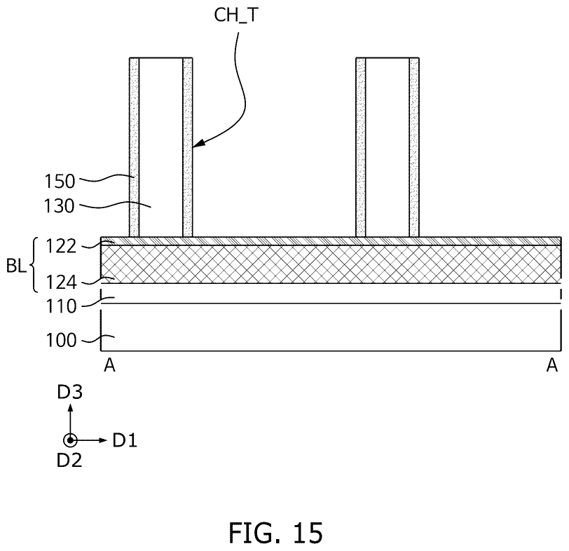

Referring to FIGS. 14 and 15, portions of the pre-blocking pattern 150_P may be removed to form the blocking pattern 150.

Specifically, portions of the pre-blocking pattern 150_P may be removed using an anisotropic etching process. Portions of the pre-blocking pattern 150_P may be removed to expose the upper surface of the bit line BL and the upper surface of the mold pattern 130. The blocking pattern 150 may be disposed on the side surface 130_SS of the mold pattern 130. The blocking pattern 150 may extend along the side surface 130_SS of the mold pattern 130. The blocking pattern 150 may overlap the mold pattern 130 in the first direction D1. The blocking pattern 150 may not overlap the mold pattern 130 in a third direction D3.

The blocking pattern 150 may be formed to define the channel trench CH_T. A bottom surface of the channel trench CH_T may be defined as the upper surface of the bit line BL and the upper surface of the bit line insulating film 125. Both side surfaces of the channel trench CH_T may be defined by two blocking patterns 150 facing each other in the first direction D1.

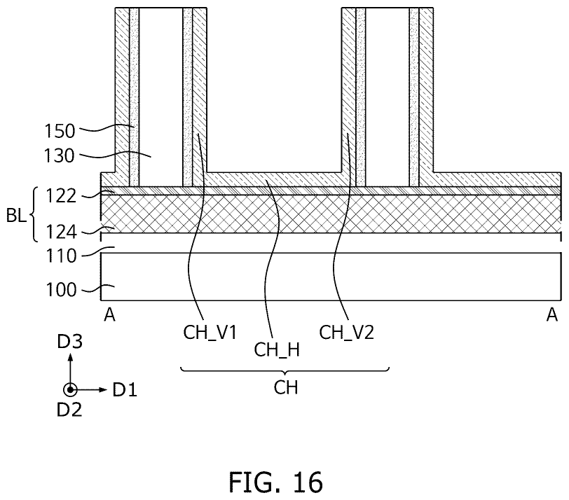

Referring to FIGS. 15 and 16, the channel structure CH may be formed in the channel trench CH_T. The channel structure CH may be formed along both sidewalls and a bottom surface of the channel trench CH_T.

The channel structure CH may include a first vertical part CH_V1, a second vertical part CH_V2, and a horizontal part CH_H. The first vertical part CH_V1 and the second vertical part CH_V2 may be formed on the side surface of the mold pattern 130. The horizontal part CH_H may be formed on the upper surface of the bit line BL.

The blocking pattern 150 may be disposed between the mold pattern 130 and the channel structure CH. One side surface of the blocking pattern 150 may be in contact with the side surface of the mold pattern 130, and the other side surface of the blocking pattern 150 may be in contact with the vertical parts CH_V1 and CH_V2 of the channel structure CH.

In some embodiments, the distance from the upper surface of the bit line BL to the upper surface of the blocking pattern 150 may be equal to the distance from the upper surface of the bit line BL to the upper surfaces of the vertical parts CH_V1 and CH_V2.

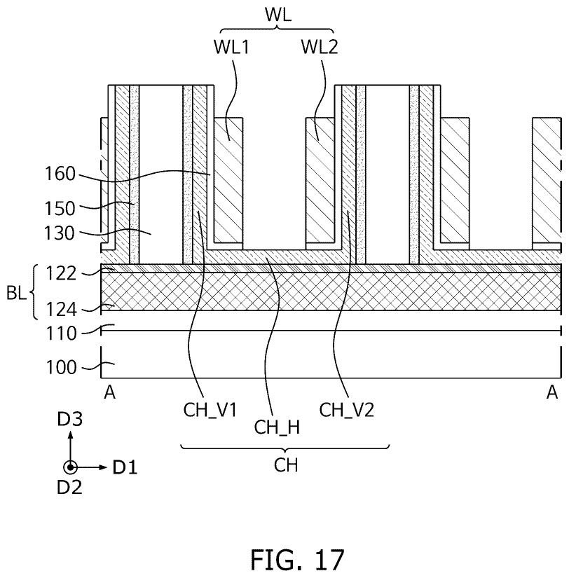

Referring to FIG. 17, the gate insulating film 160 and the word line WL may be formed on the channel structure CH.

The word line WL may extend in the second direction D2. The word line WL may include the first word line WL1 and the second word line WL2. The first word line WL1 may be disposed on one side surface of the first vertical part CH_V1. The second word line WL2 may be disposed on one side surface of the second vertical part CH_V2. The first word line WL1 and the second word line WL2 may be disposed to be spaced apart from each other in the first direction D1.

The gate insulating film 160 may be disposed between the first word line WL1 and the first vertical part CH_V1 and between the second word line WL2 and the second vertical part CH_V2. The gate insulating film 160 may extend along the inner surface of the first vertical part CH_V1, the inner surface of the second vertical part CH_V2, and a portion of the upper surface of the horizontal part CH_H.

Unlike the illustration, in some embodiments, the gate insulating film 160 may extend along the upper surface of the horizontal part CH_H. The gate insulating film 160 disposed between the first word line WL1 and the first vertical part CH_V1, and the gate insulating film 160 disposed between the second word line WL2 and the second vertical part CH_V2 may be connected to each other.

Unlike the illustration, in some embodiments, the channel structure CH may be separated into two parts. For example, the horizontal part CH_H may be separated into two parts. One separated part of the horizontal part CH_H may be connected to the first vertical part CH_V1, and the other separated part of the separated horizontal part CH_H may be connected to the second vertical part CH_V2. The upper surface of the bit line BL may be exposed between the separated horizontal parts CH_H.

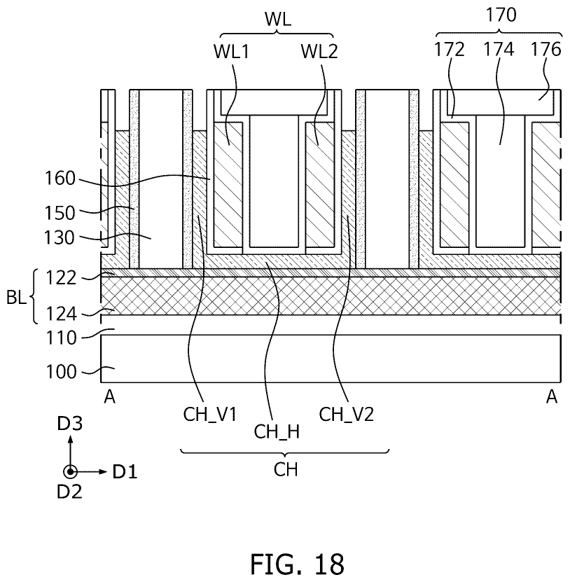

Referring to FIG. 18, the gate separation structure 170 may be formed on the channel structure CH, and a portion of the channel structure CH may be removed.

Specifically, the gate separation structure 170 may be formed on the channel structure CH and the word lines WL1 and WL2. The gate separation structure 170 may be disposed between the first word line WL1 and the second word line WL2 to separate the first word line WL1 and the second word line WL2 in the first direction D1. The gate separation structure 170 may include the gate separation liner film 172, the gate separation filling film 174, and the gate separation capping film 176.

A portion of the first vertical part CH_V1 and the second vertical part CH_V2 disposed between the blocking pattern 150 and the gate insulating film 160 may be removed. Accordingly, the height of the first vertical part CH_V1 and the second vertical part CH_V2 may be reduced. The height may refer to a length in the third direction D3. The height of the first vertical part CH_V1 may be equal to the height of the second vertical part CH_V2. The height of the first vertical part CH_V1 may be less than the height of the mold pattern 130 and the height of the blocking pattern 150.

In some embodiments, the uppermost portion of the first vertical part CH_V1 may be disposed lower than the uppermost portion of the first word line WL1. In other words, the distance from the upper surface of the bit line BL to the upper surface of the first vertical part CH_V1 may be less than the distance from the upper surface of the bit line BL to the upper surface of the first word line WL1. However, aspects are not limited thereto.

Unlike the illustration, in some embodiments, a portion of the channel structure CH may not be removed. For example, a portion of the first vertical part CH_V1 and a portion of the second vertical part CH_V2 may not be removed. The upper surface of the blocking pattern 150, the upper surface of the first vertical part CH_V1, and the upper surface of the second vertical part CH_V2 may be disposed on the same plane each other.

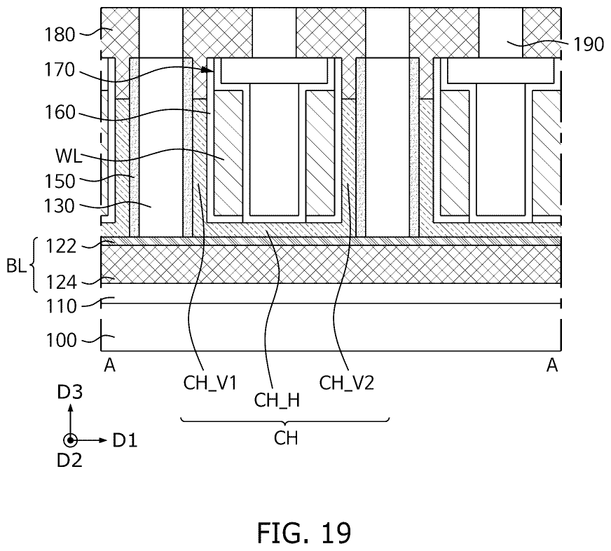

Referring to FIG. 19, the landing pads 180 may be formed on the channel structures CH, the blocking pattern 150, and the gate separation structure 170.

Each landing pad 180 may include the pad part 182 and the protrusion part 184. The pad part 182 may be formed on the gate separation structure 170. When viewed in a plan view, the pad part 182 may have various shapes such as a circle, an ellipse, a rectangle, a square, a rhombus, and a hexagon. When viewed in a plan view, a plurality of the pad parts 182 may be disposed in various forms such as a matrix form, a zigzag form, a honeycomb form, etc. along the first and second directions D1 and D2.

The interlayer insulating film 190 may be formed between adjacent pad parts 182. The upper surface of the interlayer insulating film 190 and the upper surface of the pad part 182 may be disposed on the same plane each other. The interlayer insulating film 190 may include an insulating material.

The protrusion part 184 may protrude from the pad part 182 toward the bit line BL in the third direction D3. The protrusion part 184 may be in contact with the channel structure CH. For example, the protrusion part 184 may be in contact with each of the first vertical part CH_V1 and the second vertical part CH_V2. A portion of the protrusion part 184 may overlap each of the first word line WL1 and the second word line WL2 in the first direction D1.

The protrusion part 184 may be disposed between the blocking pattern 150 and the gate insulating film 160 which are disposed in the upper portion of the channel structure CH. The blocking pattern 150 may be disposed between the mold pattern 130 and the protrusion part 184. The landing pad 180 may be spaced apart from the mold pattern 130 by the blocking pattern 150. The landing pad 104 may not be in contact with the mold pattern 130.

Referring to FIG. 2, the etching stop film 210 and the capacitor structure CAP may be formed.

The etching stop film 210 may be disposed on the landing pad 180 and the interlayer insulating film 190. The etching stop film 210 may expose the landing pad 180.

The capacitor structure CAP may be formed on the landing pad 180 and the interlayer insulating film 190. The capacitor structure CAP may include the lower electrode 222, the dielectric film 224, and the upper electrode 226. The description of the capacitor structure CAP may be the same as that described with reference to FIGS. 1 to 6.

Although certain aspects of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor memory device, comprising:
a bit line disposed on a substrate and extending in a first direction;
a channel structure disposed on the bit line and extending in a second direction perpendicular to the first direction, wherein the channel structure includes a first vertical part and a second vertical part spaced apart from the first vertical part in the first direction;
a word line disposed between the first vertical part and the second vertical part and extending in the second direction;
a gate insulating film disposed between the first vertical part and the word line and between the second vertical part and the word line;
a mold pattern disposed on at least one side of the channel structure; and
a blocking pattern disposed between the mold pattern and the channel structure.

2. The semiconductor memory device according to claim 1,
wherein a first side surface of the blocking pattern is in contact with a side surface of the mold pattern, and
wherein a second side surface of the blocking pattern opposite the first side surface is in contact with the channel structure.

3. The semiconductor memory device according to claim 1, wherein a distance from an upper surface of the bit line to an upper surface of the mold pattern is equal to a distance from the upper surface of the bit line to an upper surface of the blocking pattern.

4. The semiconductor memory device according to claim 1, wherein a distance from an upper surface of the bit line to an upper surface of the blocking pattern is equal to or greater than a distance from the upper surface of the bit line to an upper surface of the second vertical part.

5. The semiconductor memory device according to claim 1, wherein the mold pattern and the channel structure are not in contact with each other.

6. The semiconductor memory device according to claim 1,
wherein the mold pattern extends in the second direction on the bit line, and
wherein the blocking pattern covers a side surface of the mold pattern.

7. The semiconductor memory device according to claim 1, further comprising:
a landing pad disposed on the first vertical part,
wherein a portion of the landing pad is in contact with the blocking pattern.

8. The semiconductor memory device according to claim 7, further comprising:
a capacitor structure disposed on the landing pad and electrically connected to the first vertical part.

9. The semiconductor memory device according to claim 1,
wherein the channel structure further includes a horizontal part connecting the first vertical part and the second vertical part, and
wherein the horizontal part extends along an upper surface of the bit line.

10. The semiconductor memory device according to claim 1,
wherein the word line includes a first word line disposed on one side surface of the first vertical part and a second word line disposed on one side surface of the second vertical part, and
wherein the semiconductor memory device further includes a gate separation structure disposed between the first word line and the second word line.

11. The semiconductor memory device according to claim 1, wherein the blocking pattern includes a bottom part disposed between the mold pattern and the bit line.

12. A semiconductor memory device, comprising:
a bit line disposed on a substrate and extending in a first direction;
mold patterns aligned on the bit line and spaced apart from each other in the first direction, and extending in a second direction perpendicular to the first direction;
a blocking pattern disposed on a side surface of each of the mold patterns;
a channel trench defined by the blocking pattern and an upper surface of the bit line;
a channel structure disposed in the channel trench;
a word line disposed on the channel structure and extending in the second direction; and
a gate insulating film disposed between the channel structure and the word line.

13. The semiconductor memory device according to claim 12, wherein an upper surface of each of the mold patterns is disposed on the same plane as an upper surface of the blocking pattern.

14. The semiconductor memory device according to claim 12, wherein the blocking pattern includes any one of aluminum oxide, zirconium oxide, hafnium oxide, or silicon nitride.

15. The semiconductor memory device according to claim 12,
wherein the channel structure includes a first vertical part, a second vertical part spaced apart from the first vertical part in the first direction, and a horizontal part connecting the first vertical part and the second vertical part, and
wherein the first vertical part is in contact with the blocking pattern.

16. The semiconductor memory device according to claim 12, wherein the blocking pattern and the mold patterns are not overlapped with each other in a third direction perpendicular to the upper surface of the bit line.

17. The semiconductor memory device according to claim 15, wherein a distance from the upper surface of the bit line to an upper surface of the second vertical part is less than a distance from the upper surface of the bit line to the upper surface of the blocking pattern.

18. The semiconductor memory device according to claim 12, further comprising:
a landing pad electrically connected to the channel structure,
wherein the landing pad includes a pad part, and a protrusion part protruding from the pad part toward the channel structure, and
wherein the protrusion part is in contact with the blocking pattern and the channel structure.

19. The semiconductor memory device according to claim 18, wherein the protrusion part is disposed between the blocking pattern and the gate insulating film.

20. A semiconductor memory device, comprising:
a bit line disposed on a substrate and extending in a first direction;
a channel structure disposed on the bit line and extending in a second direction perpendicular to the first direction, wherein the channel structure includes a first vertical part and a second vertical part spaced apart from the first vertical part in the first direction;
a word line disposed between the first vertical part and the second vertical part and extending in the second direction;
a gate insulating film disposed between the first vertical part and the word line and between the second vertical part and the word line;
a mold pattern disposed on at least one side of the channel structure;
a blocking pattern disposed between the mold pattern and the channel structure and extending along a side surface of the mold pattern;
a landing pad disposed on each of the first and second vertical parts; and
a capacitor structure disposed on the landing pad,
wherein a distance from an upper surface of the bit line to an upper surface of the blocking pattern is equal to or greater than a distance from the upper surface of the bit line to an upper surface of the second vertical part.
